(19) United States
(12) Patent Application Publication
(10) Pub. No.: US 2010/0027203 A1
(43) Pub. Date: Feb. 4, 2010

(54) LATCH

(75) Inventor: Chi-Chung Lu, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/503,732

(22) Filed: Jul. 15, 2009

(30) Foreign Application Priority Data
Jul. 30, 2008 (CN) 200810303200.9

(51) Int. Cl. H05K 5/02

(52) U.S. Cl. 361/679.01

(57) ABSTRACT

A latch for a housing includes a first housing, a second housing, and a latching member to latch the first housing and the second housing, the first housing has a first aperture having two aperture sections therein. The second housing has a second aperture corresponding to the first aperture. The latching member includes a latching portion, the first housing engages with the second housing, the first aperture aligns with the second aperture, the latching portion passes through the first aperture and the second aperture and slides from an aperture section into another aperture section to fix the first housing and the second housing.

### BACKGROUND

1. Technical Field

The present disclosure relates to latches, particularly to a latch for a housings of electronic devices.

2. Description of Related Art

Portable electronic devices such as mobile phones and personal digital assistants (PDA) are widely used. A battery cover is usually fixed on a housing to shield a battery within the portable electronic device. The battery cover often includes a pin and an opposite hook. The base defines a receiving hole and a holding aperture. The hook is received in the holding aperture, and the cover pressed towards the housing until the pin is received in the receiving hole. Accordingly, the cover securely engages with the housing by way of the hook. However, the battery cover can disengage from the base when experiencing external force.

Therefore, there is room for improvement within the art.

### BRIEF DESCRIPTION OF THE DRAWING

Many aspects of the present latch can be better understood with reference to the following drawings. The components in the various drawings are not necessarily drawn to scale, the emphasis instead being placed upon clearly illustrating the principles of the present latch. Moreover, in the drawings, like reference numerals designate corresponding parts throughout the diagrams.

FIG. 1 is a disassembled view of latch for a housing.

FIG. 2 is an isometric view of a latching member shown in FIG. 1.

FIG. 3 is an isometric view of the latch shown in FIG. 1 during assembly.

FIG. 4 is a sectional view along the IV-IV line of FIG. 3.

FIG. 5 is an assembled view of latch shown in FIG. 1.

FIG. 6 is a sectional view along the VI-VI line of FIG. 5.

FIG. 7 is an assembled view from another angle of FIG. 5.

### DETAILED DESCRIPTION OF THE EMBODIMENT

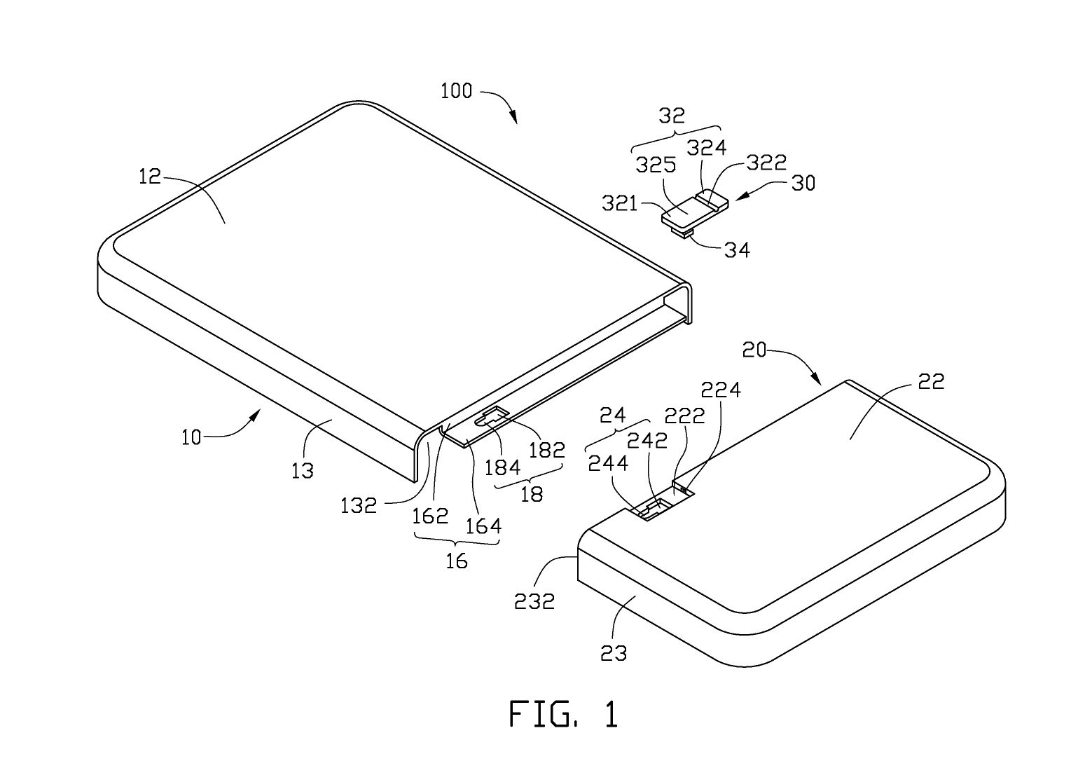

FIG. 1 shows a latch 100 used in mobile phones and other portable electronic devices, such as personal digital assistants (PDAs), digital cameras, and others. The latch 100 includes a first housing 10, a second housing 20, and a latching member 30 fixing the first housing 10 to the second housing 20.

The first housing 10 includes a first main board 12 and two sidewalls 13. The two sidewalls 13 are perpendicularly formed at two sides of the main board 12 to define a first opening 132 therebetween. The main board 12 has a flange 16 formed in the first opening 132 for connecting the seconding housing 20. The flange 16 includes a first plate portion 162 perpendicularly connecting to the main board 12, and a second plate portion 164 extending outwardly parallel with the main board 12. The second plate portion 164 defines a first through aperture 18 engaging the latching member 30. The first aperture 18 includes a first aperture section 182 and a second aperture section 184 communicating with the first aperture section 182. The first aperture section 182 is larger than the second aperture section 184.

The second housing 20 includes a second main board 22 and two sidewalls 23 perpendicular to two opposite sides of the second main board 22 to define a second opening 232. The second main board 22 defines a recess 222 proximate to the second opening 232. The recess 222 is used to receive the latching member 30. The recess 222 has a second aperture 24 defined through its bottom. The second aperture 24 has substantially the same shape and size as the first aperture 18. The second aperture 24 includes a first aperture section 242 corresponding to the first aperture section 182 and a second aperture section 244 corresponding to the second aperture section 184. The recess 222 further has a receiving hole 224 defined through one of its sidewalls engaging the latching member 30.

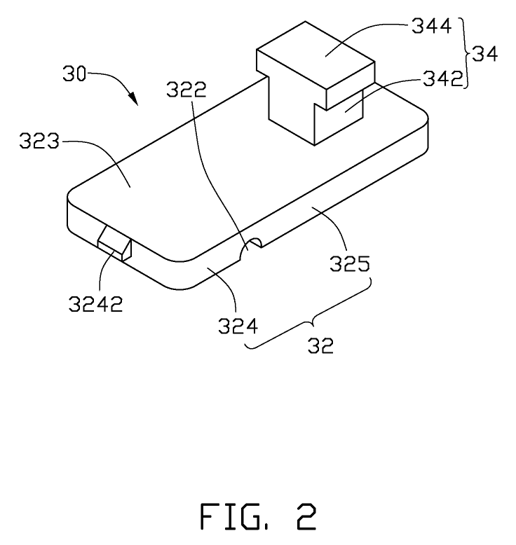

Referring further to FIG. 2, the latching member 30 can be made of rubber or other elastic materials and includes a main body 32 and a latching portion 34 connected to the main body 32. The main body 32 corresponds to the recess 222 in shape and thus can be received therein. The main body 32 includes a first surface 321 and an opposite second surface 323 protruding from the latching portion 34. A slot 322 is defined in the first surface 321 and separates the main body 32 into a first end portion 324 and a second portion 325. The first end portion 324 can be elastically collapsed relative to the second portion 325 along the slot 322. The first end portion 324 has a rib 3242 at its lateral end surface for being received in the receiving hole 224 of the second housing 20. The latching portion 34 is formed on the second portion 325 and includes a protruding pole 342 and a clipping block 344 connecting to the distal end of the protruding pole 342. The protruding pole 342 is substantially the same width as the second aperture section 184 of the first aperture 18. The clipping block 344 is the same size as the first aperture section 182 to pass through the first aperture 182.

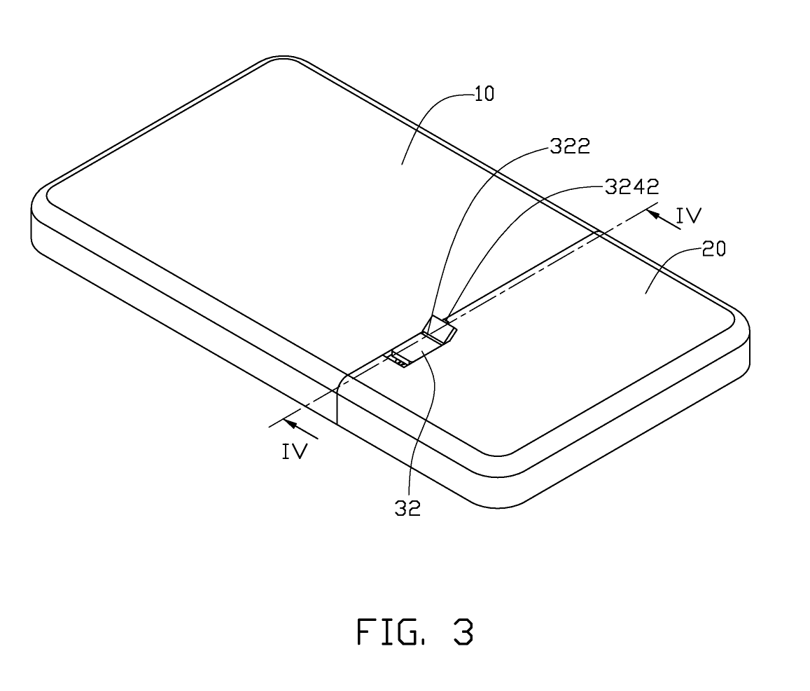

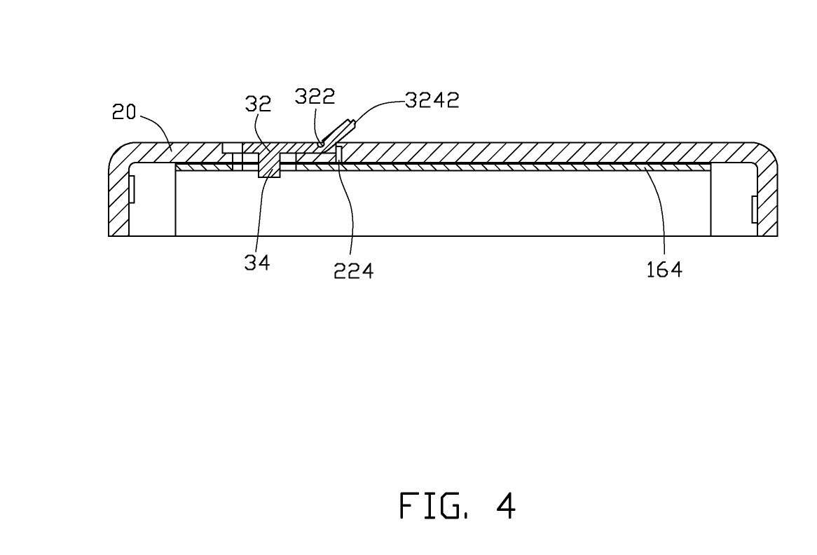

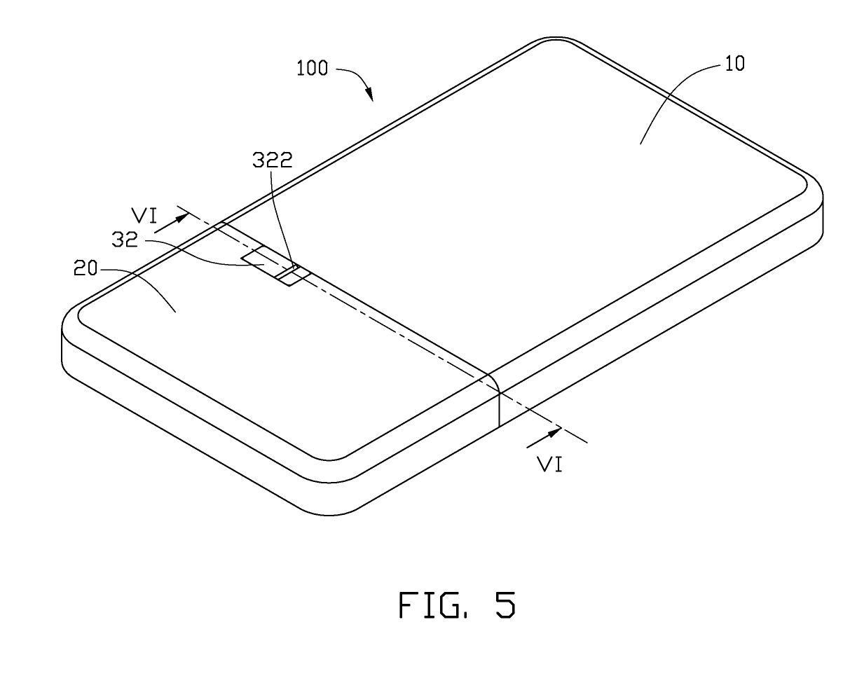

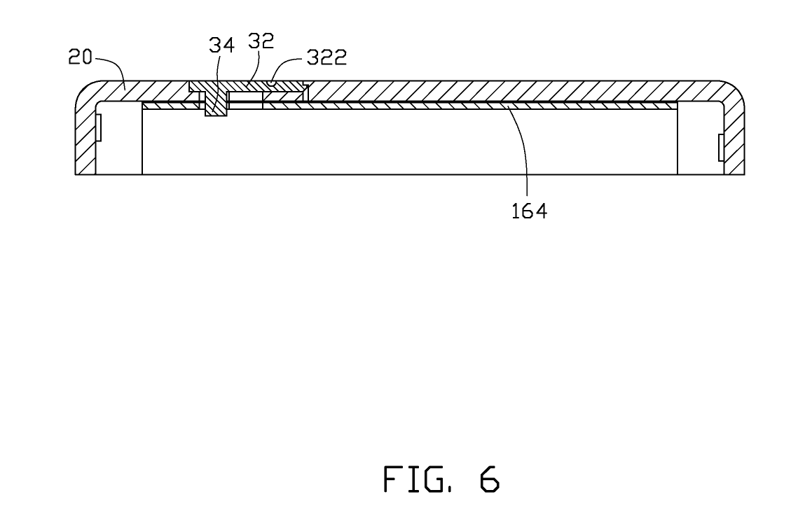

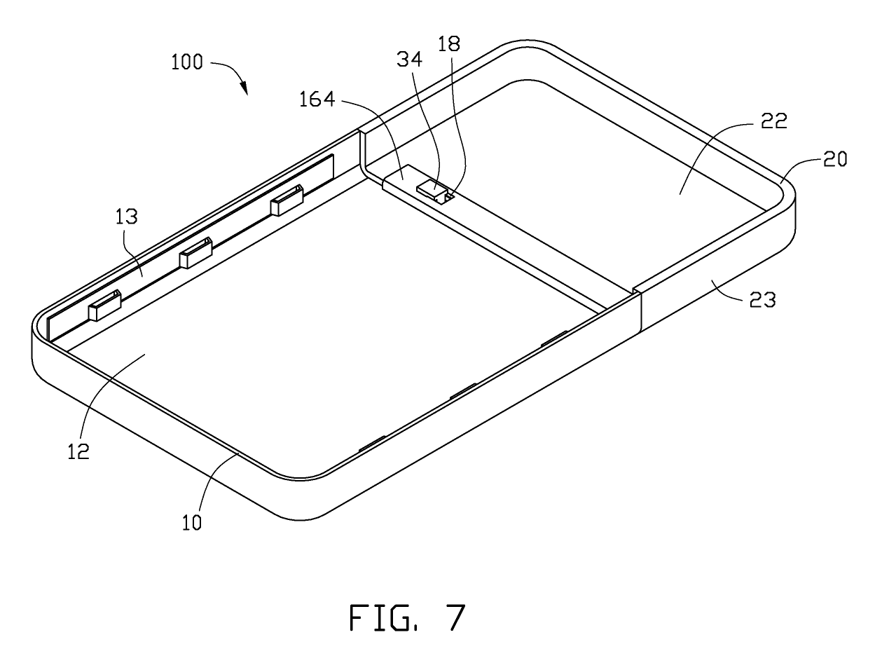

Referring to FIG. 3 through FIG. 7, during assembly of the first housing 10 to the second housing 20, the first opening 132 of the first housing 10 abuts and aligns with the second opening 232 of the second housing 20. The second main board 22 abuts the second plate portion 164 of the flange 16. The second aperture 24 of the second housing 20 aligns with the first aperture 18 of the first housing 10. The latching member 30 is assembled to latch the first housing 10 with the second housing 20. At this time, the clipping block 344 of the latching portion 34 passes through the first aperture section 182, 242. The first end portion 324 is collapsed upwardly relative to the second portion 325. As latching member 30 moves, protruding pole 342 slides into the second aperture section 184, 244. Thus, the second plate portion 164 of the first housing 10 and the second main board 22 are clipped between the clipping block 344 and the main body 32 of the latching member 30. The first end portion 324 returns to its original state and the rib 3242 is received in the receiving hole 224 of the second housing 20. The main body 32 of the latching member 30 is secured in the recess 222 of the second housing 20, and thus the first housing 10 is firmly fixed to the second housing 20 by the latching member 30.

As first housing 10 is detached from the second housing 20, an upward collapse of the first end portion 324 relative to the second end portion 325 is followed by the rib 3242 withdrawing from the receiving hole 224. Latching member 30 is slid until the latching portion 34 is withdrawn from the first aperture 18 of the first housing 10 and the second aperture 24 of the second housing 20. As such, the first housing 10 is detached from the second housing 20.

It is to be understood that the recess 222 can be omitted and second aperture 24 defined directly into the second main board 22 of second opening 232.

It is to be understood that even though numerous characteristics and advantages of the present embodiments have been set forth in the foregoing description, together with details of assemblies and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A latch for a housing, comprising:
a first housing defining a first aperture comprising a first aperture section and a second aperture section communicating with the first aperture section, and the first aperture section being larger than the second aperture section;
a second housing defining a recess and forming a second aperture corresponding to the first aperture in the bottom of the recess; and
a latching member including a main body and a latching portion protruding from the main body,
wherein when the first housing engages the second housing, the first aperture aligns with the second aperture, the latching portion passes through the first aperture and the second aperture and slides from the first aperture section into the second aperture section to latch the first housing and the second housing, with the main body received in the recess.

2. The latch for a housing as claimed in claim 1, wherein the first aperture and the second aperture have the same shape.

3. The latch for a housing as claimed in claim 1, wherein the latching portion comprises a protruding pole and a clipping block formed at the end of the protruding pole, wherein the clipping block passes through the first aperture section, and the protruding pole is received in the second aperture section to clip the first housing and the second housing.

4. The latch for a housing as claimed in claim 1, wherein the main body of the latching member is elastic and comprises a first surface defining a slot therein, the slot dividing the main body into a first end portion and a second end portion, and wherein the first end portion can be collapsed relative to the second portion along the slot.

5. The latch for a housing as claimed in claim 1, wherein the main body of the latching member comprises a second surface opposite to the first surface, with the latching portion formed on the second surface.

6. The latch for a housing as claimed in claim 5, wherein the first end portion forms a rib in the lateral end surface thereof to be received in the receiving hole defined in the sidewall of the recess.

7. The latch for a housing as claimed in claim 5, wherein the first housing comprises a first opening forming a flange, wherein the first aperture is defined in the flange, the second housing includes a second opening defining the recess, and the first opening engages the second opening.

8. A latch for a housing, comprising:
a first housing defining a first aperture having a first aperture section and a second aperture section communicating with the first aperture section, and the first aperture section is larger than the second aperture section;
a second housing defining a second aperture corresponding to the first aperture; and
a latching member comprising a latching portion,
wherein when the first housing engages the second housing, the first aperture aligns with the second aperture, the latching portion passes through the first aperture and the second aperture and slides from the first aperture section into the second aperture section to fix the first housing and the second housing.

9. The latch for a housing as claimed in claim 8, wherein the first aperture and the second aperture have the same shape.

10. The latch for a housing as claimed in claim 8, wherein the first aperture comprises a first aperture section and a second aperture section communicating with the first aperture section, and the first aperture section is wider than the second aperture section.

11. The latch for a housing as claimed in claim 8, wherein the latching portion comprises a protruding pole and a clipping block formed at the end of the protruding pole, the clipping block passes through the first aperture section, and the protruding pole is received in the second aperture section to clip the first housing and the second housing.
